(19) United States
(12) Patent Application Publication
(10) Pub. No.: US 2024/0120241 A1
(43) Pub. Date: Apr. 11, 2024

(54) PACKAGING DEVICE CAPABLE OF DETECTING RISK OF IMPACT OF ELECTROSTATIC CHARGES

(71) Applicant: PANJIT INTERNATIONAL INC., Kaohsiung City (TW)

(72) Inventors: Chung-Hsiung HO, Kaohsiung City (TW); Chien-Chun Wang, Tainan City (TW); Li-Qiang Ye, Kaohsiung City (TW); Chi-Hsueh Li, Tainan City (TW)

(21) Appl. No.: 18/072,690

(22) Filed: Nov. 30, 2022

(30) Foreign Application Priority Data
Oct. 11, 2022 (TW) 111138481

(51) Int. Cl. H01L 21/66; G01R 31/00; G01R 31/28; H01L 21/56; H01L 29/86

(52) U.S. Cl. CPC H01L 22/30; G01R 31/002; G01R 31/281; H01L 21/561; H01L 21/568; H01L 29/86; H01L 29/456

(57) ABSTRACT

The present invention provides an electrostatic charge detecting packaging device comprising a carrier, multiple dies, and multiple electrostatic-charge-sensitive components; the carrier has a surface; the dies are mounted on the surface of the carrier; and the electrostatic-charge-sensitive components are mounted on the surface of the carrier; since an electrostatic voltage tolerance of each of the electrostatic-charge-sensitive components is lower than an electrostatic voltage tolerance of each of the dies, accumulated electrostatic charges are more likely to discharge towards the electrostatic-charge-sensitive components than towards the dies, and as such, by electrically testing whether the electrostatic-charge-sensitive components are functioning normally when packaging the dies, the present invention allows personnel to debug for knowing which packaging steps exactly cause more serious problems that lead to damaging electrostatic discharges in the dies.

### CROSS-REFERENCE TO RELATED APPLICATION(S)

This application claims the priority benefit of TW Application Serial No. 111138481 filed on Oct. 11, 2022, the entirety of which is hereby incorporated by reference herein and made a part of the specification.

### BACKGROUND OF THE INVENTION

### 1. Field of the Invention

The present invention relates to a packaging device, more particularly a packaging device capable of detecting a risk of impact of electrostatic charges.

### 2. Description of the Related Art

A die is a semiconductor component diced from a wafer. The die, with its designated function, is packaged into a packaging product through packaging.

With reference to FIG. 9, packaging usually includes a step of die bonding. Die bonding involves mounting multiple dies 80 and multiple conductive bulks 800 on a carrier 81, wherein each of the dies 80 is electrically connected to one of the conductive bulks 800.

With reference to FIG. 10, furthermore, through steps of molding, grinding, tracing, etc., the dies 80 are diced through sawing, wherein each of the dies 80 and each of the corresponding conductive bulks 800 are diced into a packaging product 82 as shown in FIG. 10. Each packaging product 82 includes a packaging body 820, a first connection point 821, and a second connection point 822. The first connection point 821 and the second connection point 822 of each packaging product 82 respectively electrically connect two electrodes of the die 80.

As packaging requires multiple steps to complete, some of the steps for packaging can easily generate and accumulate electrostatic charges. For instance, steps such as mold removal or grinding can easily generate and accumulate electrostatic charges in the dies 80. To prevent the dies 80 from being damaged by electrostatic discharges, ion fans are normally installed on packaging machines. By blowing ionic wind to the dies 80, ions within the ionic wind are able to neutralize the electrostatic charges built up in the dies 80.

However, the installation of the ionic fans only relies on human experiences of packaging personnel. In other words, the ionic fans are only roughly directed to blow the ionic wind at estimated locations of the dies 80. Whether the electrostatic charges built up in the dies 80 are successfully neutralized may only be known once the packaging of the dies 80 is completed and the dies 80 are tested for yield percentages. This means that the packaging personnel have no way of knowing which of the packaging steps exactly causes more serious problems that lead to damaging electrostatic discharges in the dies 80. As a result, the packaging steps are systematically unable to improve and be debugged for having less of the dies 80 damaged by electrostatic discharges.

### SUMMARY OF THE INVENTION

With regard to the aforementioned issues, the present invention provides a packaging device capable of detecting a risk of impact of electrostatic charges. The main goal of the present invention is to overcome the inability to debug for knowing which packaging steps exactly cause more serious problems that lead to damaging electrostatic discharges in dies.

The packaging device includes
a carrier, having a surface;
multiple dies, mounted on the surface of the carrier; and
multiple electrostatic-charge-sensitive components, mounted on the surface of the carrier; wherein an electrostatic voltage tolerance of each of the electrostatic-charge-sensitive components is lower than an electrostatic voltage tolerance of each of the dies.

By mounting the electrostatic-charge-sensitive components on the surface of the carrier during die bonding, the electrostatic-charge-sensitive components of the present invention are able to stay with the dies throughout the packaging steps. This way, packaging personnel are able to debug for knowing which packaging steps exactly cause more serious risks and problems that lead to damaging electrostatic discharges in the dies by monitoring when exactly the electrostatic-charge-sensitive components become dead throughout the packaging steps. Since the electrostatic voltage tolerance of each of the electrostatic-charge-sensitive components is lower than the electrostatic voltage tolerance of each of the dies, when any one of the electrostatic-charge-sensitive components becomes dead, an assessment is made that the dies in surrounding locations of the dead electrostatic-charge-sensitive component have higher risks of being damaged by electrostatic discharges. A packaging product containing the dies with higher risks of being damaged by electrostatic discharges is then reframed from being handed to a client. Furthermore, more ionic fans can be added to the corresponding packaging step that causes the death of the electrostatic-charge-sensitive component. As such, for this particular packaging step, more inflow of ionic winds blown from more of the ionic fans is able to better decrease electrostatic charges from building up in the dies, and thus further decrease chances of the dies from being damaged by possible electrostatic discharges.

### BRIEF DESCRIPTION OF THE DRAWINGS

FIG. 1 is a three-dimensional (3D) perspective view of an embodiment of an electrostatic charge detecting packaging device of the present invention.

FIG. 2 is a 3D perspective view of a packaging device made from the present invention.

FIG. 3 is a 3D perspective view of another embodiment of the present invention, wherein electrostatic-charge-sensitive components mounted on a surface of a carrier are spaced differently.

FIG. 4 is a side perspective view of an example of an electrostatic-charge-sensitive component of the present invention.

FIG. 5 is a side perspective view of another example of an electrostatic-charge-sensitive component of the present invention.

FIGS. 6A to 6K are a part of packaging steps relating to the electrostatic charge detecting packaging device of the present invention.

FIG. 7 is a top perspective view of a packaging step relating to the electrostatic charge detecting packaging device of the present invention.

FIG. 8 is a top perspective view of another packaging step relating to the electrostatic charge detecting packaging device of the present invention.

FIG. 9 is a perspective view of mounting dies and conductive bulks on a surface of a carrier in conventional die bonding.

FIG. 10 is a 3D perspective view of a packaging product after conventional packaging.

### DETAILED DESCRIPTION OF THE INVENTION

The present invention provides an electrostatic charge detecting packaging device. A manufacturing method of the electrostatic charge detecting packaging device is also disclosed. The manufacturing method can be integrated into various types of semiconductor packaging methods, such as panel-level packaging (PLP), substrate packaging, lead frame packaging, fan out packaging, or other types of packaging methods. Conventional semiconductor packaging usually includes at least one of the steps of molding, grinding, tracing, and sawing. Since these steps are conventionally known, the manufacturing method relating to the present invention will omit describing these steps.

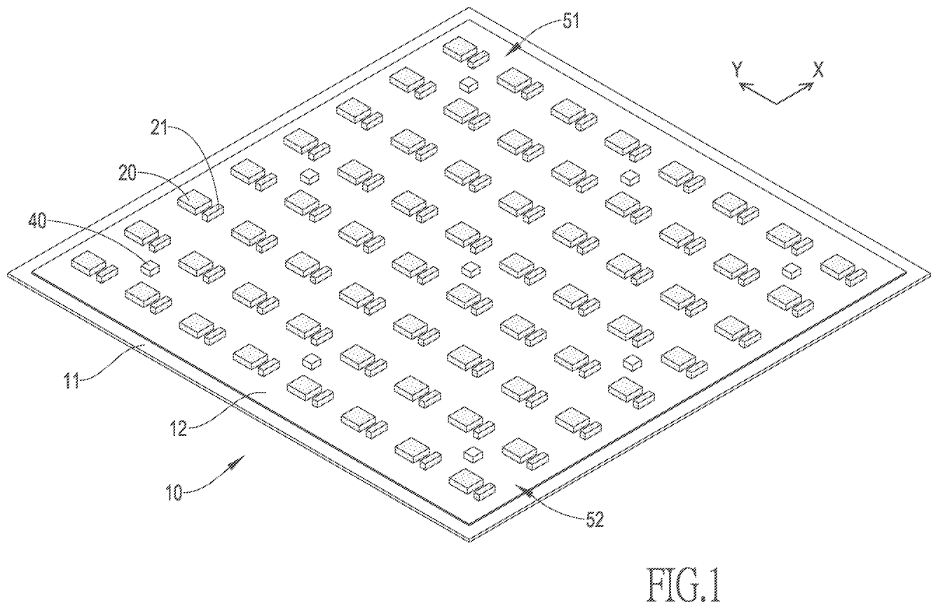

With reference to FIG. 1, in an example of PLP, die bonding involves mounting multiple dies 20 on a surface of a carrier 10. The carrier 10 includes a carrier board 11 and a film 12 formed on the carrier board 11. In the present example, a top surface and a bottom surface of each of the dies 20 respectively include an electrode pad, and each of the dies 20 is respectively electrically connected to a conductive bulk 21. In other words, the dies 20 and the conductive bulks 21 are mounted on a surface of the film 12. In the said tracing step, a conductive bridging component, such as a wire or a lead frame, may be mounted to electrically connect one of the electrode pads of each of the dies 20 to one of the conductive bulks 21.

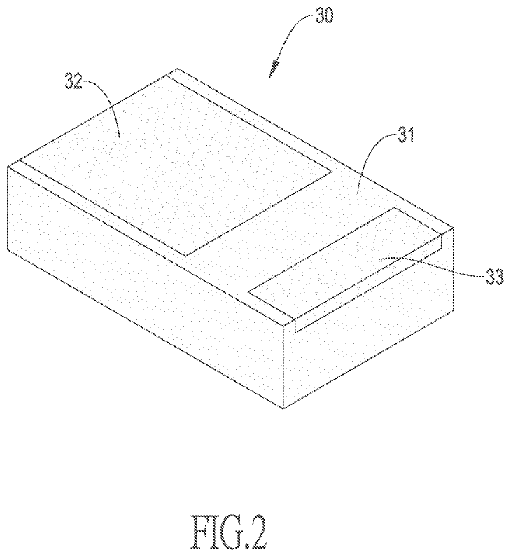

With reference to FIG. 2, after packaging is completed, a packaging product 30 includes a packaging body 31, a first connection point 32, and a second connection point 33. The first connection point 32 and the second connection point 33 respectively electrically connect the two electrode pads of one of the dies 20.

With further reference to FIG. 1, during die bonding, the manufacturing method for the device of the present invention involves mounting multiple electrostatic-charge-sensitive components 40 on the surface of the carrier 10. The electrostatic-charge-sensitive components 40 are mounted among the dies 20, allowing the electrostatic-charge-sensitive components 40 to be placed apart from positions of the dies 20. The electrostatic-charge-sensitive components 40, however, are free to be mounted elsewhere than just between the dies 20. The electrostatic-charge-sensitive components 40 may also be mounted in a dedicated area, as discussed in later parts of the explanation.

The electrostatic charge detecting packaging device of the present invention thereby includes the carrier 10, the multiple dies 20, and the multiple electrostatic-charge-sensitive components 40. With reference to FIG. 1, the dies are mounted in a matrix along an X axis and a Y axis. The dies 20 are spaced with an X axis scribe line 51 along any two of the adjacent dies 20 along the X axis, and the dies 20 are spaced with a Y axis scribe line 52 along any two of the adjacent dies 20 along the Y axis. The carrier 10 as a whole includes multiple of the X axis scribe lines 51 and multiple of the Y axis scribe lines 52. Each of the X axis scribe lines 51 is perpendicular to each of the Y axis scribe lines 52. Each of the electrostatic-charge-sensitive components 40 is mounted on one of the X axis scribe lines 51, on one of the Y axis scribe lines 52, or on an intersection between one of the X axis scribe lines 51 and one of the Y axis scribe lines 52. The electrostatic-charge-sensitive components 40 shown in FIG. 1 are placed on intersections between the X axis scribe lines 51 and the Y axis scribe lines 52.

Any two of the adjacent electrostatic-charge-sensitive components 40 in FIG. 1 are equally spaced along the X axis and the Y axis. In other words, the electrostatic-charge-sensitive components 40 shown in FIG. 1 are evenly distributed on the surface of the carrier 10. In other embodiments, the electrostatic-charge-sensitive components 40 are mounted in the dedicated area of the carrier 10, wherein the dedicated area is, for example, an area most likely to experience damaging electrostatic discharges in the carrier 10 according to past experience.

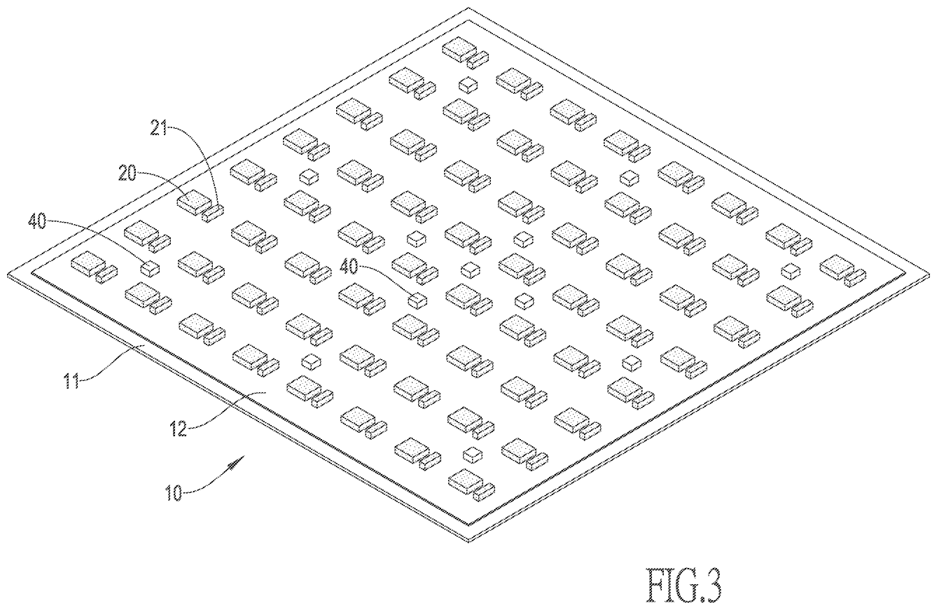

With reference to FIG. 3, also in other embodiments, the electrostatic-charge-sensitive components 40 are distributed on the surface of the carrier 10 in varying densities. For instance, a center of the carrier 10 has higher distribution density of the electrostatic-charge-sensitive components 40 and more of the electrostatic-charge-sensitive components 40.

Furthermore, an electrostatic voltage tolerance of each of the electrostatic-charge-sensitive components 40 is lower than an electrostatic voltage tolerance of each of the dies 20. This means that each of the electrostatic-charge-sensitive components 40 is less tolerant to electrostatic voltages from accumulated electrostatic charges than each of the dies 20. In this embodiment, the electrostatic-charge-sensitive components 40 in fact may also be semiconductor dies.

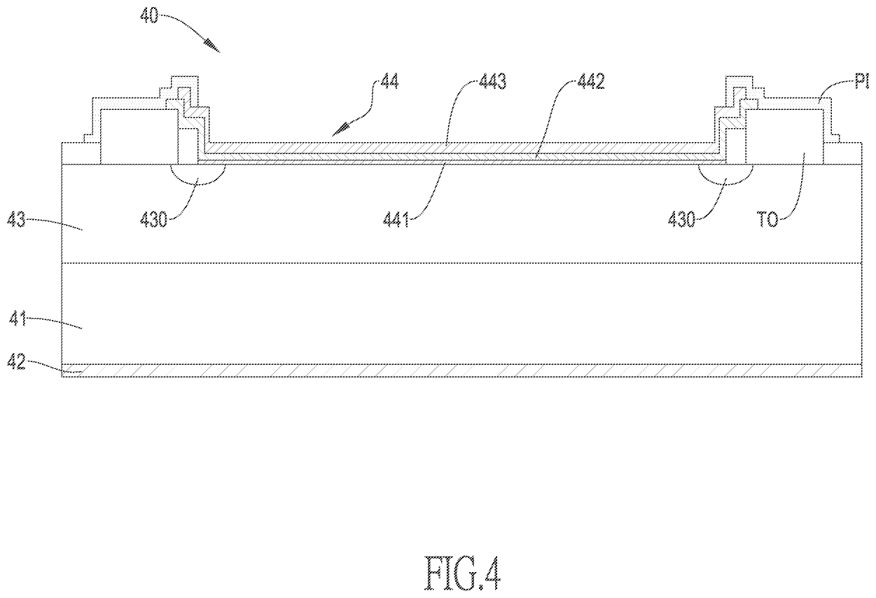

With reference to FIG. 4, each of the electrostatic-charge-sensitive components 40 includes a substrate 41, a bottom electrode pad 42 mounted on a bottom surface of the substrate 41, an epitaxial layer 43 formed on a top surface of the substrate 41, and a top electrode pad 44 mounted on a top surface of the epitaxial layer 43. The substrate 41 is an N-type silicon substrate, and the epitaxial layer 43 is also an N-type epitaxial layer. The top surface of the epitaxial layer 43 includes a formulation of two P-type areas 430, and two opposite horizontal sides of the top electrode pad 44 are connected to the two P-type areas 430. The top electrode pad 44 is a composite layered structure, and the top electrode pad 44 includes a metallic silicide layer 441, an alloy metal layer 442, and a top layer 443. The metallic silicide layer 441, the alloy metal layer 442, and the top layer 443 are layered in the said order from bottom to top of the composite layered structure. More particularly, the metallic silicide layer 441 is mounted on the top surface of the epitaxial layer 43, and two opposite horizontal sides of the metallic silicide layer 441 overlap and connect the two P-type areas 430. The alloy metal layer 442 is, for example, a Tungsten-Titanium (TiW) layer. The top layer 443 is, for example, an aluminum (Al) layer. Thermal oxide layers TO are mounted on two opposite sides of the top surface of the epitaxial layer 43 in shape of stair cases. Two opposite sides (or two opposite ends) of the alloy metal layer 442 and the top layer 443 are layered and mounted on the thermal oxide layers TO. A protection layer PI is respectively mounted on top of the two opposite sides (or two opposite ends) of the alloy metal layer 442 and the top electrode pad 44 for covering and protection. The protection layer PI is respectively a polymide layer, and the bottom electrode pad 42 is a composite layered structure with a Nickel-Titanium (NiTi) layer and a silver (Ag) layer.

When die bonding, a side of each of the electrostatic-charge-sensitive components 40 with the top electrode pad 44 or the bottom electrode pad 42 is mounted on the film 12. The bottom electrode pad 42 and the top electrode pad 44 are then electrically tested to determine whether the corresponding electrostatic-charge-sensitive component 40 is functioning.

As shown in FIG. 4, each of the electrostatic-charge-sensitive components has the top electrode pad 44 and the bottom electrode pad 42 respectively on top and bottom of each of the electrostatic-charge-sensitive components 40. In other embodiments, each of the electrostatic-charge-sensitive components 40 may also have electrode pads mounted on a single surface (the top surface or the bottom surface) of each of the electrostatic-charge-sensitive components 40 for conducting testing signals, testing whether the corresponding electrostatic-charge-sensitive component 40 is functioning.

With reference to FIG. 5, in this embodiment, each of the electrostatic-charge-sensitive components 40 includes a substrate 41′, an epitaxial layer 43′ formed on a top surface of the substrate 41′, and a first electrode pad 451′ and a second electrode pad 452′ mounted on a top surface of the epitaxial layer 43′. For each of the electrostatic-charge-sensitive components 40, a bottom surface of the substrate 41′ is then mounted to the film 12 as shown in FIG. 3, allowing the first electrode pad 451′ and the second electrode pad 452′ free to be electrically tested to determine whether the corresponding electrostatic-charge-sensitive component 40 is functioning.

The substrate 41′ is an N-type silicon substrate, and the epitaxial layer 43′ is also an N-type epitaxial layer. The top surface of the epitaxial layer 43′ includes a formulation of two P-type areas 430′ and two metallic silicide layers 431′, wherein the two metallic silicide layers 431′ are spaced apart. The two P-type areas 430′ are formed on two horizontal opposite sides of one of the two metallic silicide layers 431′. In other words, one of the two metallic silicide layers 431′ is connected between the two P-type areas 430′. The first electrode pad 451′ is spaced apart from the second electrode pad 452′, and the first electrode pad 451′ and the second electrode pad 452′ are respectively mounted on the two metallic silicide layers 431′. In this embodiment, the first electrode pad 451′ and the second electrode pad 452′ are aluminum pads (Al pads), and an oxide layer 46′ is formed on the epitaxial layer 43′. Furthermore, each of the electrostatic-charge-sensitive components 40 also includes an insulation layer 47′, a first conduction support layer 481′, and a second conduction support layer 482′. The insulation layer 47′ covers the oxide layer 46′ on the epitaxial layer 43′, the first electrode pad 451′, and the second electrode pad 452′. The insulation layer 47′ includes a first opening 471′ and a second opening 472′. The first opening 471′ and the second opening 472′ are located respectively corresponding to locations of the first electrode pad 451′ and the second electrode pad 452′, allowing surfaces of the first electrode pad 451′ and the second electrode pad 452′ to partially be exposed respectively through the first opening 471′ and the second opening 472′. The second opening 472′ is placed relatively far from the first electrode pad 451′ on the second electrode pad 452′. The first conduction support layer 481′ and the second conduction support layer 482′ are parts of an under bump metallization (UBM) composite layered structure, for example a titanium layer/copper layer/copper layer (Ti/Cu/Cu layered) composite layered structure. The first conduction support layer 481′ and the second conduction support layer 482′ are respectively mounted on the insulation layer 47′. The first conduction support layer 481′ connects the first electrode pad 451′ through the first opening 471′, and the second conduction support layer 482′ connects the second electrode pad 452′ through the second opening 472′.

As shown in FIG. 5, a size of the second conduction support layer 482′ is smaller than a size of the second electrode pad 452′, and since the second conduction support layer 482′ is placed relatively far from the first electrode pad 451′ on the second electrode pad 452′, a gap between the first conduction support layer 481′ and the second conduction support layer 482′ is greater than a gap between the first electrode pad 451′ and the second electrode pad 452′. A plating solder layer 49′ is respectively mounted on top surfaces of the first conduction support layer 481′ and the second conduction support layer 482′, allowing the corresponding electrostatic-charge-sensitive component 40 to be electrically tested.

Please be noted that the electrostatic-charge-sensitive components 40 are free to be elsewise in other embodiments than illustrated in FIGS. 4 and 5 as long as the electrostatic voltage tolerance of each of the electrostatic-charge-sensitive components 40 is lower than the electrostatic voltage tolerance of each of the dies 20. The lower the electrostatic voltage tolerance of each of the electrostatic-charge-sensitive components 40 is, the more sensitive each of the electrostatic-charge-sensitive components 40 is towards accumulated electrostatic charges. Conversely, when the electrostatic voltage tolerance of each of the electrostatic-charge-sensitive components 40 is close to the electrostatic voltage tolerance of each of the dies 20, each of the electrostatic-charge-sensitive components 40 and each of the dies 20 are more equally sensitive towards accumulated electrostatic charges. For example, since a size of each of the electrostatic-charge-sensitive components 40 is smaller than a size of each of the dies 20, each of the electrostatic-charge-sensitive components 40 of smaller size has lower electrostatic voltage tolerance. Though, of course, the size of each of the electrostatic-charge-sensitive components 40 is only part of many factors that determine the electrostatic voltage tolerance of each of the electrostatic-charge-sensitive components 40. The electrostatic voltage tolerance of each of the electrostatic-charge-sensitive components 40 still depends on a model of each of the electrostatic-charge-sensitive components 40. In an embodiment, the electrostatic voltage tolerance of each of the electrostatic-charge-sensitive components 40 is of a particular ratio to the electrostatic voltage tolerance of each of the dies 20. For example, when the electrostatic voltage tolerance of each of the dies 20 is ±0.5 kilovolts (KVs), and the electrostatic voltage tolerance of each of the electrostatic-charge-sensitive components 40 is of 0.8 times to the electrostatic voltage tolerance of each of the dies 20, then as a result the electrostatic voltage tolerance of each of the electrostatic-charge-sensitive components 40 is ±0.4 KVs. Similarly, when the electrostatic voltage tolerance of each of the dies 20 is ±30 KVs, the electrostatic voltage tolerance of each of the electrostatic-charge-sensitive components 40 is ±24 KVs. The electrostatic voltage tolerance of each of the electrostatic-charge-sensitive components 40 is also free to be elsewise in other embodiments in relations to the electrostatic voltage tolerance of each of the dies 20.

Since the present invention places the electrostatic-charge-sensitive components 40 when die bonding, the electrostatic-charge-sensitive components 40 are able to stay with the dies 20 throughout rest of the packaging steps. Furthermore, since the electrostatic voltage tolerance of each of the electrostatic-charge-sensitive components 40 is lower than the electrostatic voltage tolerance of each of the dies 20, when electrostatic discharges occur during the packaging steps, the electrostatic-charge-sensitive components 40 are more likely to be damaged and destroyed by the electrostatic discharges than the dies 20. Since electrode pads of the electrostatic-charge-sensitive components 40 are exposed throughout the packaging steps, packaging personnel are able to use a digital multimeter (DMM) or other measuring devices to measure and to determine whether each of the electrostatic-charge-sensitive components 40 is functioning or dead by connecting to the electrode pads. For example, when one of the electrostatic-charge-sensitive components 40 is measured to have forward bias or reverse bias, in a voltage measurement or in a current measurement, greater than a threshold range, then the corresponding electrostatic-charge-sensitive component 40 is determined to be dead. Having forward bias or reverse bias greater than the threshold range means having the voltage measurement or the current measurement greater than an upper threshold or less than a lower threshold. On the other hand, when one of the electrostatic-charge-sensitive components 40 is measured to have forward bias or reverse bias within the threshold range, meaning when the voltage measurement or the current measurement is less than or equal to the upper threshold and greater than or equal to the lower threshold, the corresponding electrostatic-charge-sensitive components 40 is determined to be functioning.

The following examples demonstrate other steps involved in the packaging steps. Although these following steps are considered conventional, the following demonstration explains how the electrostatic-charge-sensitive components 40 stay with the dies 20 in the packaging steps.

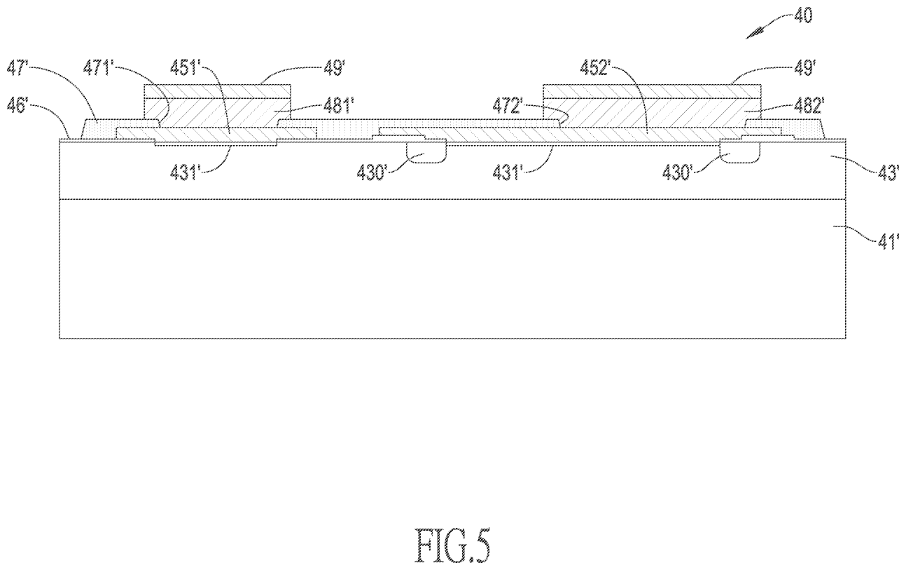

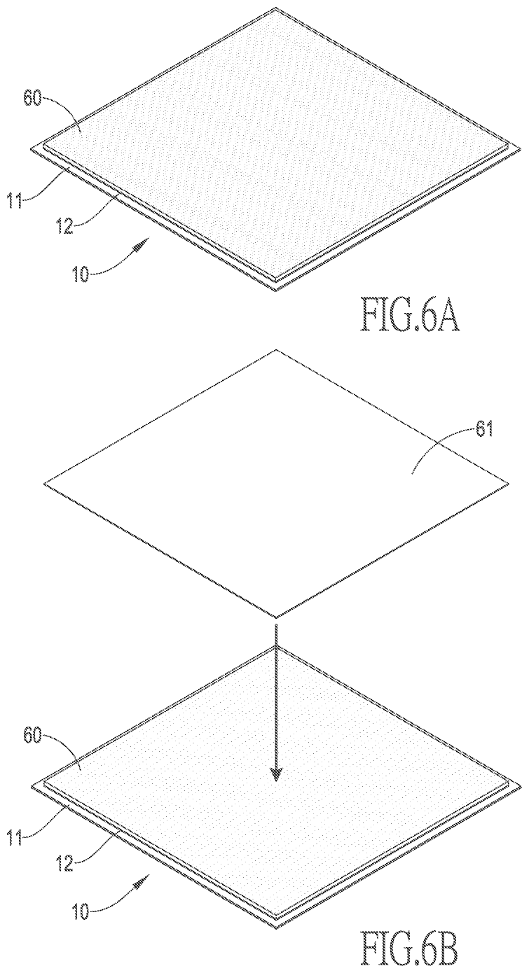

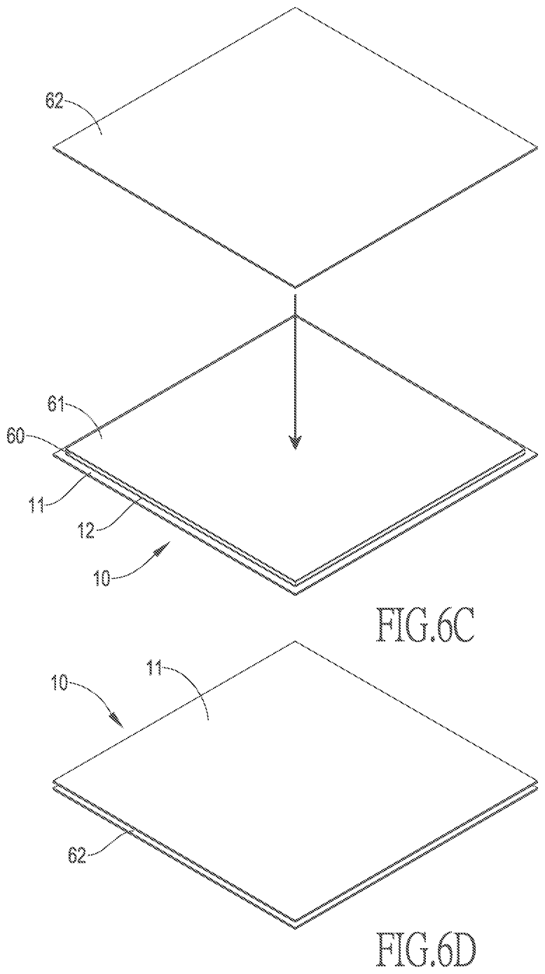

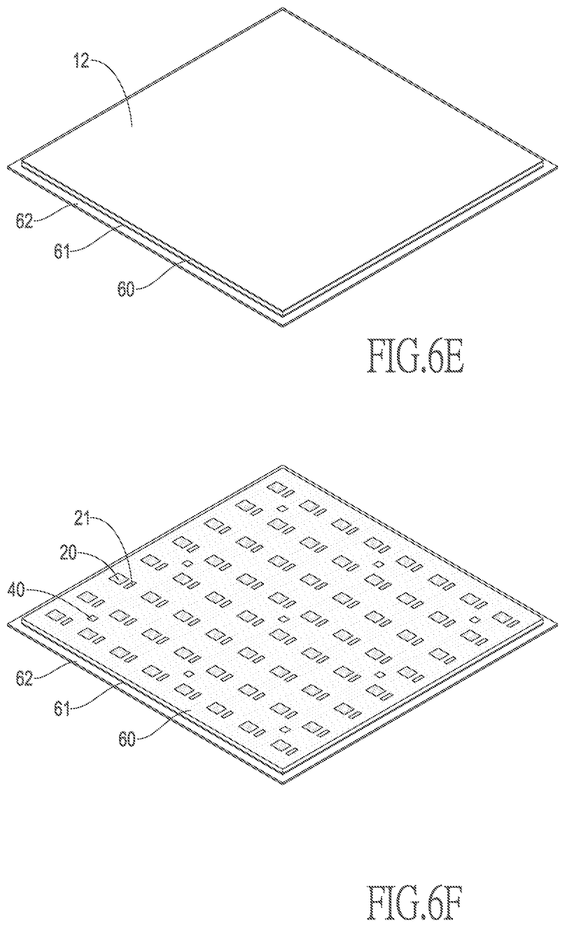

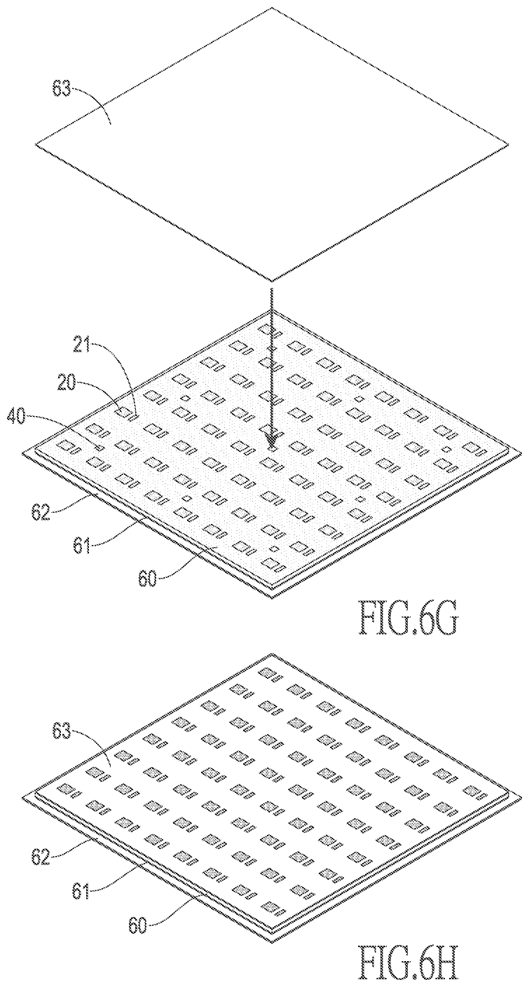

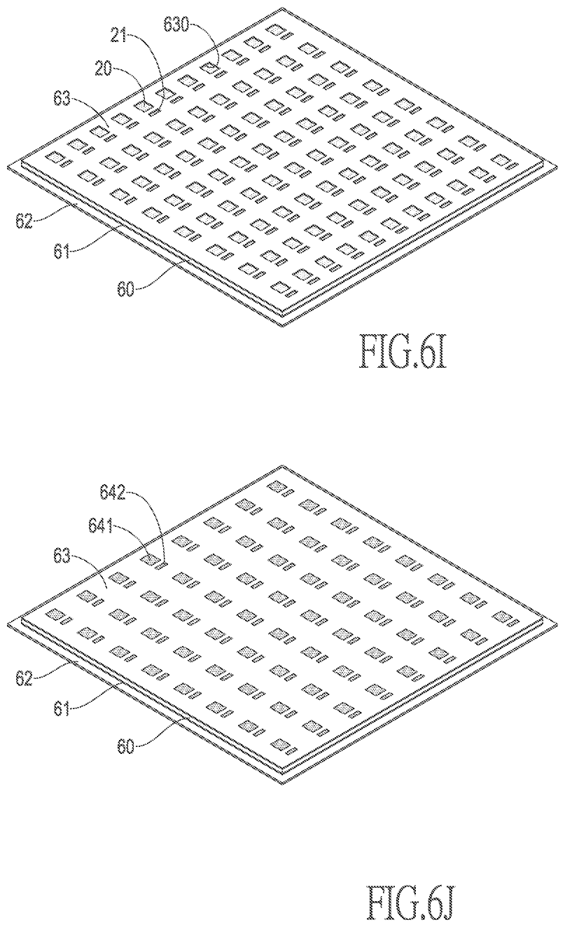

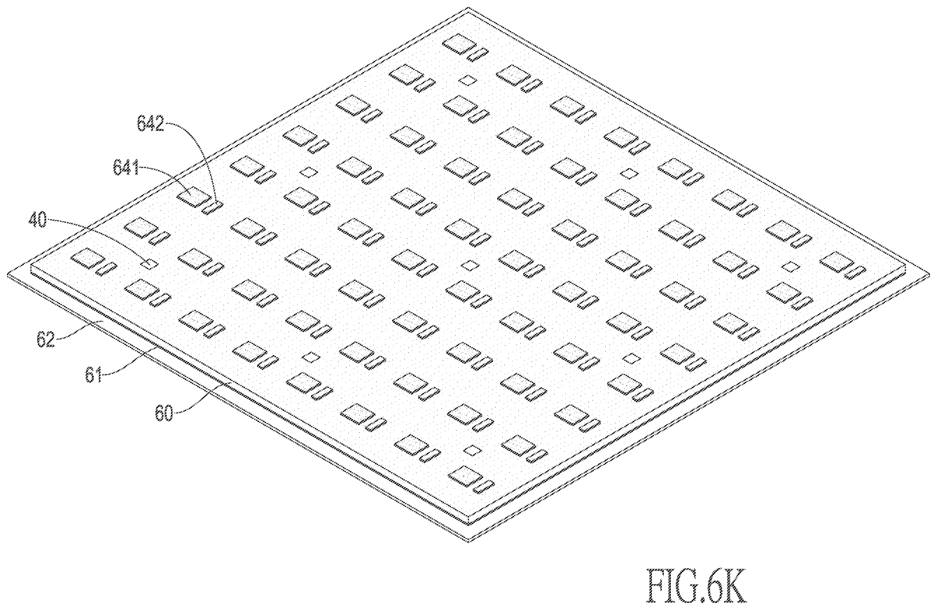

With reference to FIG. 6A, after die bonding as shown in FIG. 1, a film layer 60 is formed on the carrier 10. The film layer 60 covers the dies 20, the conductive bulks 21, and the electrostatic-charge-sensitive components 40.

With reference to FIG. 6B, a second film layer 61 is formed on the film layer 60.

With reference to FIG. 6C, a second carrier board 62 is mounted on the second film layer 61.

With reference to FIG. 6D, the carrier 10 is flipped, allowing the carrier 10 to be on top of the second carrier board 62.

With reference to FIG. 6E, the film 12 is exposed by removing the carrier board 11 shown in FIG. 6D.

With reference to FIG. 6F, a surface of the film layer 60, the dies 20, the conductive bulks 21, and the electrostatic-charge-sensitive components 40 are exposed by removing the film 12 shown in FIG. 6E.

With reference to FIG. 6G, a dry film photoresist layer 63 is formed to cover the film layer 60, the dies 20, the conductive bulks 21, and the electrostatic-charge-sensitive components 40.

With reference to FIG. 6H, the dry film photoresist layer 63 is lithographically exposed according to positions of the dies 20 and the conductive bulks 21, and after exposing, films are removed from the dry film photoresist layer 63.

With reference to FIG. 6I, multiple grooves 630 are formed by developing the dry film photoresist layer 63. The grooves 630 respectively correspond to positions of the dies 20 and the conductive bulks 21, allowing the dies 20 and the conductive bulks 21 to be exposed through the grooves 630.

With reference to FIG. 6J, conductive layers are mounted respectively in the grooves 630. More particularly, each of the dies 20 is connected to a first conductive layer 641, and each of the conductive bulks 21 is connected to a second conductive layer 642.

With reference to FIG. 6K, the dry film photoresist layer 63 is removed as shown in FIG. 6J, allowing the electrostatic-charge-sensitive components 40 to be exposed from the film layer 60.

As previously mentioned, the packaging steps relating to the electrostatic charge detecting packaging device of the present invention can be integrated into various types of semiconductor packaging methods. The electrostatic-charge-sensitive components 40 are free to be distributed elsewhere than between the dies 20, as the electrostatic-charge-sensitive components 40 may also be mounted in the dedicated area of the carrier 10.

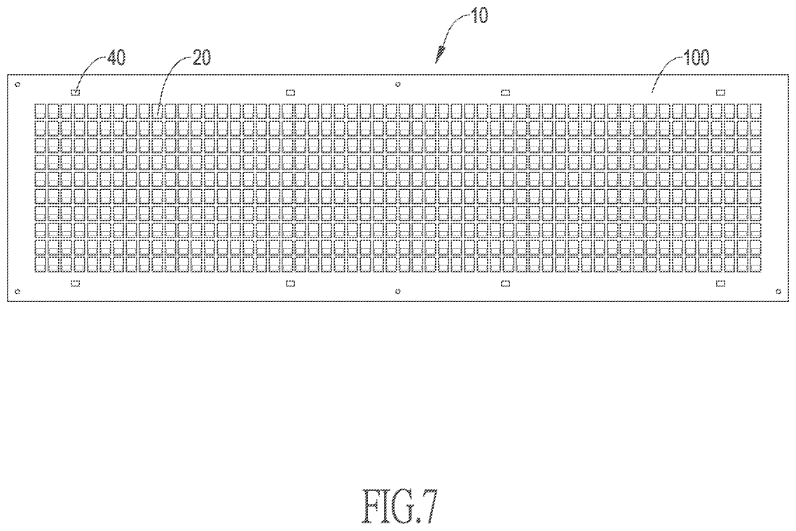

With reference to FIG. 7, therefore, apart from the aforementioned PLP, substrate packaging as mentioned in FIG. 7 involves having the dies 20 mounted on the surface of the carrier 10, wherein the carrier 10 is a circuit board with redistribution functionalities. The dies 20 are clustered on the surface of the carrier 10, and the electrostatic-charge-sensitive components 40 are distributed in peripheral areas 100 of the carrier 10. As such, the electrostatic-charge-sensitive components 40 would stay with the dies 20 in the packaging steps.

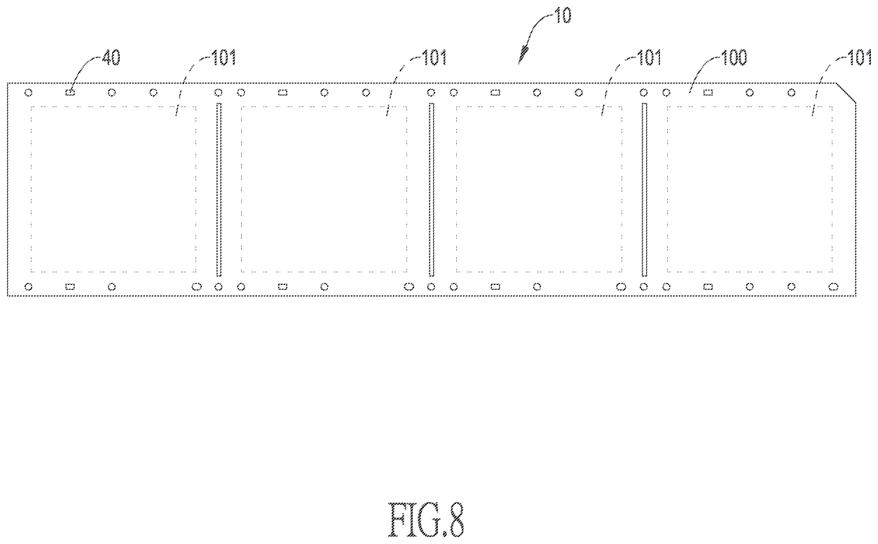

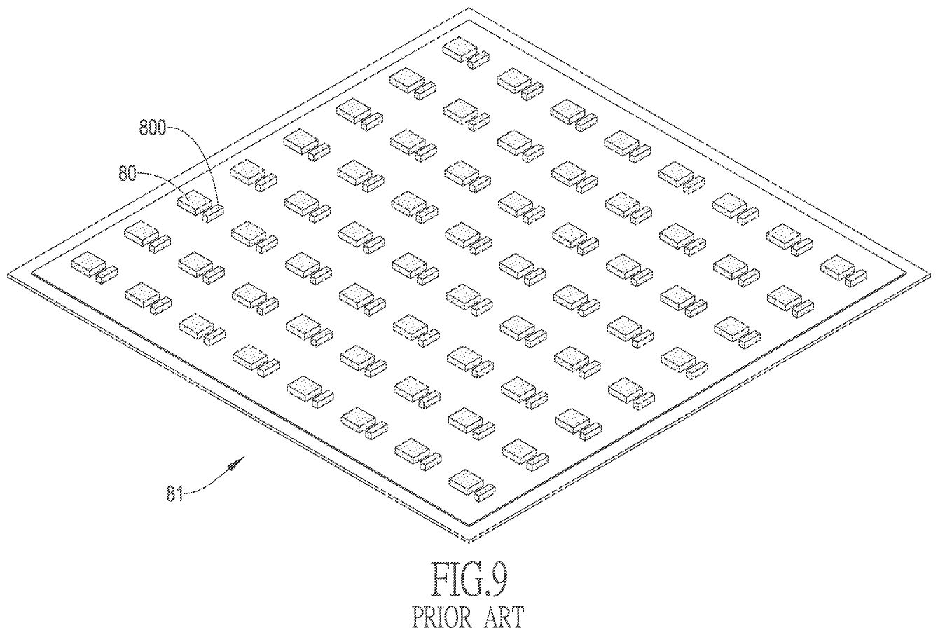

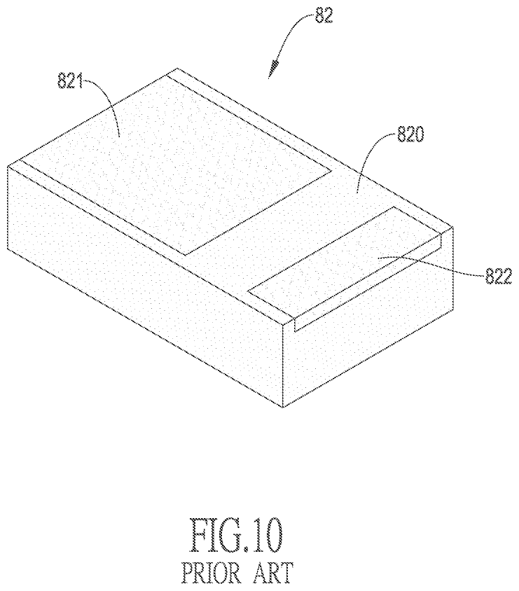

With reference to FIG. 8, in the lead frame packaging example, the carrier 10 is a lead frame with groove patterns, wherein the groove patterns provide places for distribution of the dies 20 (not shown in figures). In this embodiment, the said lead frame is a metallic lead frame, such as a lead frame constructed from copper filaments. In another embodiment, the lead frame may be an alloy lead frame or elsewise. The groove patterns (not shown in figures) are formed in a middle area 101 of the carrier 10, and the electrostatic-charge-sensitive components 40 are distributed in peripheral areas 100 of the carrier 10. As such, the electrostatic-charge-sensitive components 40 would stay with the dies 20 in the packaging steps.

Because the electrostatic-charge-sensitive components 40 stay with the dies 20 in the few packaging steps as mentioned above, and because a surface of each of the electrostatic-charge-sensitive components 40 is exposed in parts of the packaging steps, such as the steps mentioned in FIG. 6F and FIG. 6K, when the electrode pads are exposed from the exposing electrostatic-charge-sensitive components 40, personnel are able to electrically connect the electrode pads and conduct electrical tests to determine whether each of the electrostatic-charge-sensitive components 40 is functioning. When any one of the electrostatic-charge-sensitive components 40 is determined to be dead, an assessment is made that the dies 20 in surrounding locations of the dead electrostatic-charge-sensitive component 40 have higher risks of being damaged by electrostatic discharges. A packaging product containing the dies 20 with higher risks of being damaged by electrostatic discharges is then reframed from being handed to a client. Furthermore, more ionic fans can be added to the corresponding packaging step that causes the death of the electrostatic-charge-sensitive component. As such, for this particular packaging step, more inflow of ionic winds blown from more of the ionic fans is able to better decrease electrostatic charges from building up in the dies 20, and thus further decrease chances of the dies 20 from being damaged by possible electrostatic discharges.

What is claimed is:

1. A packaging device capable of detecting a risk of impact of electrostatic charges, comprising:
a carrier, having a surface;
multiple dies, mounted on the surface of the carrier; and
multiple electrostatic-charge-sensitive components, mounted on the surface of the carrier; wherein an electrostatic voltage tolerance of each of the electrostatic-charge-sensitive components is lower than an electrostatic voltage tolerance of each of the dies.

2. The packaging device as claimed in claim 1, wherein:
the electrostatic-charge-sensitive components are mounted among the dies, and each of the electrostatic-charge-sensitive components is mounted on a scribe line.

3. The packaging device as claimed in claim 1, wherein:
the electrostatic-charge-sensitive components are mounted among the dies;
the carrier comprises multiple X axis scribe lines and multiple Y axis scribe lines, and each of the electrostatic-charge-sensitive components is mounted on one of the X axis scribe lines.

4. The packaging device as claimed in claim 1, wherein:
the electrostatic-charge-sensitive components are mounted among the dies;
the carrier comprises multiple X axis scribe lines and multiple Y axis scribe lines, and each of the electrostatic-charge-sensitive components is mounted on one of the Y axis scribe lines.

5. The packaging device as claimed in claim 1, wherein:
the electrostatic-charge-sensitive components are mounted among the dies;
the carrier comprises multiple X axis scribe lines and multiple Y axis scribe lines, and each of the electrostatic-charge-sensitive components is mounted on an intersection between one of the X axis scribe lines and one of the Y axis scribe lines.

6. The packaging device as claimed in claim 1, wherein:
the electrostatic-charge-sensitive components are evenly distributed on the surface of the carrier.

7. The packaging device as claimed in claim 2, wherein:
the electrostatic-charge-sensitive components are evenly distributed on the surface of the carrier.

8. The packaging device as claimed in claim 3, wherein:
the electrostatic-charge-sensitive components are evenly distributed on the surface of the carrier.

9. The packaging device as claimed in claim 4, wherein:
the electrostatic-charge-sensitive components are evenly distributed on the surface of the carrier.

10. The packaging device as claimed in claim 5, wherein:
the electrostatic-charge-sensitive components are evenly distributed on the surface of the carrier.

11. The packaging device as claimed in claim 1, wherein:
the electrostatic-charge-sensitive components are mounted in a dedicated area of the carrier.

12. The packaging device as claimed in claim 2, wherein:
the electrostatic-charge-sensitive components are mounted in a dedicated area of the carrier.

13. The packaging device as claimed in claim 3, wherein:
the electrostatic-charge-sensitive components are mounted in a dedicated area of the carrier.

14. The packaging device as claimed in claim 4, wherein:
the electrostatic-charge-sensitive components are mounted in a dedicated area of the carrier.

15. The packaging device as claimed in claim 5, wherein:
the electrostatic-charge-sensitive components are mounted in a dedicated area of the carrier.

16. The packaging device as claimed in claim 1, wherein:
the electrostatic-charge-sensitive components are distributed on the surface of the carrier in varying densities.

17. The packaging device as claimed in claim 2, wherein:
the electrostatic-charge-sensitive components are distributed on the surface of the carrier in varying densities.

18. The packaging device as claimed in claim 3, wherein:
the electrostatic-charge-sensitive components are distributed on the surface of the carrier in varying densities.

19. The packaging device as claimed in claim 4, wherein:
the electrostatic-charge-sensitive components are distributed on the surface of the carrier in varying densities.

20. The packaging device as claimed in claim 1, wherein:
the electrostatic-charge-sensitive components are distributed in peripheral areas of the carrier.
